(19) United States
(12) Patent Application Publication
(10) Pub. No.: US 2025/0068445 A1
(43) Pub. Date: Feb. 27, 2025

(54) METHOD AND SYSTEM FOR EMULATING A CHIP DESIGN WITH HETEROGENEOUS HARDWARE

(71) Applicant: SHANGHAI UNIVISTA INDUSTRIAL SOFTWARE GROUP CO., LTD., SHANGHAI (CN)

(72) Inventors: Pei-hsin HO, Taipei (TW); Fan YANG, SHANGHAI (CN); Li SHANG, SHANGHAI (CN); Ruiyao PU, SHANGHAI (CN); Yiwei SUN, SHANGHAI (CN)

(21) Appl. No.: 18/805,582

(22) Filed: Aug. 15, 2024

(30) Foreign Application Priority Data
Aug. 24, 2023 (CN) 202311071149.4

(51) Int. Cl. G06F 9/455; G06F 30/34

(52) U.S. Cl. CPC G06F 9/45508; G06F 30/34

(57) ABSTRACT

The present invention relates to the field of chip verification technology, and more particularly, to a method and system for emulating a chip design with heterogeneous hardware. It involves the interconnection of microprocessors and FPGAs, where the microprocessors have shorter object code compilation times than the FPGAs' bit files, and the FPGAs have higher emulation performance. The DUT is partitioned into n microprocessors and m FPGAs. The design module D, which requires debugging and correction, is assigned to the microprocessors. Then, the n microprocessors and the m FPGAs are controlled to perform emulation and debugging. Since the compilation time for a microprocessor hosting the design module D is shorter than when using FPGAS, and while ensuring that the mature design modules in the FPGAs have high emulation performance, the method successfully integrates the advantages of the iterative speed of microprocessors and the emulation performance of FPGAs.

### CROSS-REFERENCE TO RELATED APPLICATIONS

This application claims priority to Chinese Patent Application No. CN202311071149.4, titled “A Method and System for Heterogeneous Hardware Emulation,” filed on Aug. 24, 2023, with the Chinese National Intellectual Property Administration. The entire content of this application is incorporated herein by reference.

### FIELD

The present invention relates to the field of chip verification technology, and more particularly, to a method and system for emulating a chip design with heterogeneous hardware.

### BACKGROUND

Chip design, also known as integrated circuit (IC) design, refers to the design process targeted at integrated circuits or very large-scale integrated (VLSI) circuits. Chip design generally uses hardware description languages (HDLs) such as Verilog, System Verilog, or VHDL to describe the structure and behavior of digital systems in textual form. After chip design completion, the process moves to tape-out; any fatal issues in the design can lead to tape-out failure, which incurs high costs. To reduce the risk of tape-out failure, comprehensive verification of the chip design is necessary before tape-out to identify and rectify issues in a timely manner, ensuring successful tape-out.

Digital chip logic function verification includes software simulation and hardware emulation. Hardware emulators typically consist of field-programmable gate arrays (FPGAs) and microprocessors. When using FPGAs for hardware emulation, the compilation process is time-consuming and has a low turnaround time but good emulation performance. Conversely, using microprocessors for hardware emulation results in high turnaround time but relatively poor emulation performance. Currently, no hardware emulator balances emulation performance and turnaround time effectively. Thus, there is a pressing need for a solution that divides IC designs between FPGAs and microprocessors to leverage their respective advantages in hardware emulation.

### SUMMARY

To address the aforementioned technical problems, the present invention proposes: According to some embodiments of the present disclosure, a method for emulating a chip design with heterogeneous hardware, including the following steps:
S200: Obtaining interconnected hardware emulators Emu and K memory units. Emu includes N microprocessors and M FPGAs; The compilation time of the object code of the microprocessors is shorter than the compilation time of the bit files of the FPGAs, and the emulation performance of the FPGAs is higher than that of the microprocessors. The N microprocessors, M FPGAs, and K memory units are interconnected via L physical interconnect links, where K≥0, N≥1, M≥1, and L≥1.
S400: Obtaining the chip design DUT, which includes a design module D that requires debugging and correction.
S600: Partitioning the DUT to generate n object code for the n microprocessors and m bit files for the m FPGAs, where 0<n≤N and 0<m≤M. This includes:
S620: Partitioning the DUT into n microprocessors and m FPGAs, where D is assigned the microprocessors, resulting in n first-type design modules for the microprocessors and m second-type design modules for the FPGAs.
S640: Allocating physical interconnect links for the transmission signals between the n first-type design modules and the m second-type design modules, resulting in signal transmission configuration modules for both types of design modules.
S660: Compiling each first-type design module and its signal transmission configuration module to generate object code for the microprocessors, resulting in n object code; similarly, compiling each second-type design modules and its signal transmission configuration module to generate bit files for the FPGAs, resulting in m bit files.
S800: Storing the n object code in memories of the n microprocessors and writing the m bit files into the m FPGAs, Controlling the n microprocessors and the m FPGAS to perform emulation and debugging.

According to some other embodiments of the present disclosure, a system for emulating a chip design with heterogeneous hardware, comprising interconnected hardware emulators Emu, K memory units, and a system compiler. The Emu includes N microprocessors and M FPGAs, The compilation time of the object code of the microprocessors is shorter than the compilation time of the bit files of the FPGAs, and the emulation performance of the FPGAs is higher than that of the microprocessors; There are L physical interconnect links between the N microprocessors and the M FPGAs, where N≥1, M≥1, and L≥1; The system compiler includes partitioners, routers, microprocessor compilers, FPGA chip compilers, and a server. Components include:

The partitioner divides the chip design DUT into n microprocessors and m FPGAs, where the DUT includes a design module D that requires debugging and correction, and is assigned to the microprocessors, resulting in n first-type design modules for the microprocessors and m second-type design modules for the FPGAs.

The router allocates physical interconnect links for the transmission signals between the n first-type design modules and the m second-type design modules, resulting in signal transmission configuration modules for both types of design modules.

The microprocessor compiler generates object code for each first-type design module and its signal transmission configuration module.

The FPGA compiler generates bit files for each second-type design module and its signal transmission configuration module.

The server stores the n object code in memories of the n microprocessors and write the m bit files into the m FPGAs, and controls the n microprocessors and the m FPGAs to perform emulation and debugging.

The invention has the following advantages:

The invention provides a method and system for emulating a chip design with heterogeneous hardware. It interconnects microprocessors and FPGAs to form a heterogeneous system and divides the chip design into multiple parts, assigning these parts to microprocessors and FPGAs. The design module D that needs to be debugging and correction is assigned to the microprocessor. Each microprocessor and FPGA processes its respective design module, compiles it to generate object code and bit file, and then performs co-simulation. Compared to using only FPGA or microprocessor as a hardware emulator, this invention only requires recompiling the microprocessor when debugging and modifying design modules. This makes the turnaround time of the simulation equivalent to the turnaround time of the microprocessor, integrating the simulation performance to be close to that of the FPGA. Therefore, this invention combines the advantages of the microprocessor's turnaround time and the FPGA's simulation performance.

### DESCRIPTION OF DRAWINGS

To better illustrate the technical solutions in the embodiments of the present invention, the drawings referenced in the descriptions are briefly introduced. The drawings merely represent some embodiments of the invention and are not exhaustive. Ordinary technical personnel in this field can obtain other drawings based on these without creative labor.

FIG. 1 is a flowchart illustrating a method for emulating a chip design with heterogeneous hardware according to some embodiments.

FIG. 2 is a schematic diagram illustrating a system compiler in a system for emulating a chip design with heterogeneous hardware according to some embodiments.

### DETAILED DESCRIPTION

The technical solutions in the embodiments of the present invention are clearly and comprehensively described below with reference to the drawings. The described embodiments represent only part of the invention and not all possible embodiments. Based on these embodiments, any other embodiments obtained by ordinary technical personnel in the field without creative labor fall within the scope of the invention.

Unless otherwise defined, all the technical and scientific terms used herein have the same meanings as those commonly understood by those skilled in the art.

Hardware emulators include FPGAs and microprocessors. FPGAs execute emulation tasks directly without software simulation of circuit behavior, providing better emulation performance. Layout and routing are crucial steps in FPGA compilation, determining the physical arrangement and electrical connections of the logic circuits on the FPGA. Due to the extensive optimization and constraint settings required, layout and routing consume significant time, leading to long FPGA compilation times and slow turnaround time. If a bug is found during emulation, each time a bug is fixed, the FPGA containing the bug needs to recompile the modified chip design, resulting in long turnaround time and low debugging ease. Microprocessors, without the need for layout and routing, offer fast turnaround time but lower emulation performance compared to FPGAs.

To merge the benefits of emulation performance and turnaround time, the invention combines FPGAs and microprocessors. Critical design modules D requiring frequent debugging and correction are assigned to microprocessors, while mature design modules P are assigned to FPGAs. Each module is compiled into object code and bit file for their respective hardware emulators, which then operate in coordinated emulation. By only recompiling the microprocessor-assigned design modules when changes are made, the overall turnaround time increases significantly compared to using FPGAs alone, while retaining near-FPGA-level emulation performance.

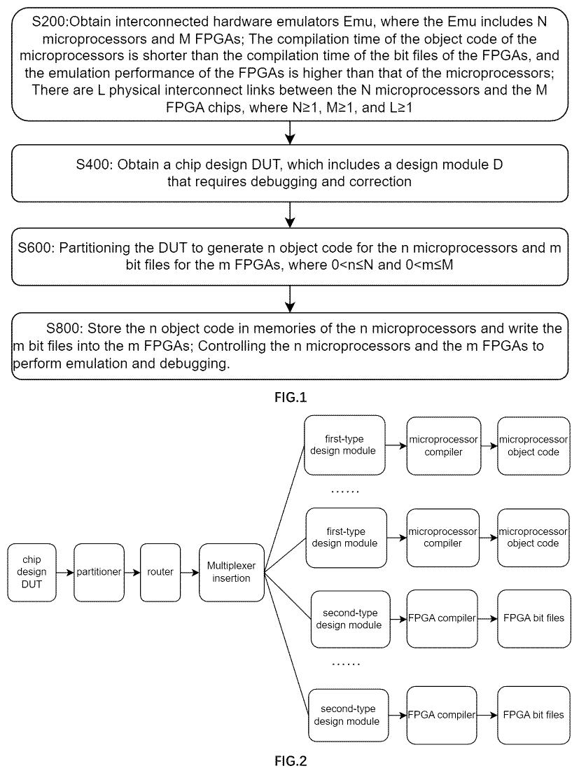

As shown in FIG. 1, a method for emulating a chip design with heterogeneous hardware, which includes:

S200: Obtaining interconnected hardware emulators Emu and K memory units. Emu includes N microprocessors and M FPGAs; The compilation time of the object code of the microprocessors is shorter than the compilation time of the bit files of the FPGAs, and the emulation performance of the FPGAs is higher than that of the microprocessors. The N microprocessors, M FPGAs, and K memory units are interconnected via L physical interconnect links, where K≥0, N≥1, M≥1, and L≥1.

It should be noted that emulating a chip design with heterogeneous hardware refers to simulation conducted using two different types of chips: FPGA and microprocessors. Optionally, the microprocessor may be a Boolean Processor or a multi-core processor. Any microprocessor in the prior art that can be used for hardware emulation and has a compilation speed greater than that of an FPGA falls within the scope of the present invention.

Preferably, the microprocessor is a Boolean Processor. It should be noted that a Boolean Processor is a type of microprocessor specifically designed for handling Boolean operations, including AND, OR, and NOT operations. During the compilation process to generate object code, the Boolean Processor does not require the layout and routing process, resulting in a faster compilation speed than an FPGA and higher debugging ease.

It should be noted that the architectures of microprocessors and FPGAs determine their respective compilation speeds and simulation performances. Generally, for these two types of chips, the compilation speed of microprocessors is greater than that of FPGAs, while the simulation performance is lower than that of FPGAs. In special cases, when the architecture of the microprocessor is extremely complex, it may result in a compilation speed slower than that of FPGAs or a simulation performance lower than that of FPGAs.

The memory is used to support debugging or simulating memories in the chip design. Optionally, the memory is Random Access Memory (RAM). Further, the memory may be Dynamic RAM (DRAM) or Static RAM (SRAM).

Multiple physical interconnect links exist between the N microprocessors, M FPGAs, and K memories, with each physical interconnect link serving as an interconnect channel. In the interconnect structure, the u-th memory is connected to f1 microprocessors and f2 FPGAs, where f1 and f2 are both greater than or equal to 0.

S400: Obtaining the chip design DUT, which includes a design module D that requires debugging and correction.

In this context, the chip design DUT refers to the RTL (Register Transfer Level) code of the chip design, which includes the design module D and the mature design module P. The design module D, which needs debugging and correction, is independently designed by the user and requires significant debugging attention. This module is designated by the user. The mature design module P refers to circuit modules that have undergone extensive verification and do not require substantial modification or adjustment, such as IP cores or well-verified circuit modules from a previous generation.

S600: Partitioning the DUT to generate n object code for the n microprocessors and m bit files for the m FPGAs, where 0<n≤N and 0<m≤M. This includes. Furthermore, the steps of processing the DUT by the system compiler include:

S620: Partitioning the DUT into n microprocessors and m FPGAs, where D is assigned the microprocessors, resulting in n first-type design modules for the microprocessors and m second-type design modules for the FPGAs.

For convenience of description, FPGAs and microprocessors are collectively referred to as hardware emulators, and this will not be stated again hereafter.

It should be noted that in the embodiments of the present invention, “first type” and “second type” do not indicate any sequence or importance. Except for the ‘first type’ and ‘second type’ labels used in the specific classification step, “first type” and “second type” are used solely for distinguishing relationships. Specifically, features associated with the microprocessors are described as first type features, while features associated with the FPGAs are described as second type features. This distinction will not be reiterated hereafter. For example, first-type design modules refer to design modules partitioned for the microprocessors, and second-type design modules refer to design modules partitioned for the FPGAs.

It should be noted that the scale of the chip design DUT is generally large, while the hardware resources of a single hardware emulator are limited. A single hardware emulator cannot accommodate the entire chip design. Therefore, the chip design DUT needs to be divided into n+m design modules, with each design module implemented on a corresponding hardware emulator.

Among these, the design module D requires significant debugging and correction and needs to undergo multiple recompilations. Therefore, design module D is assigned to the microprocessor to accelerate the compilation speed during simulation, thereby improving simulation efficiency. When module D needs to be recompiled, this also accelerates the recompilation speed, further enhancing overall simulation efficiency. Mature design modules outside of module D, which do not require extensive debugging and correction and focus more on simulation without needing multiple recompilations, are primarily assigned to the FPGA due to its superior simulation performance.

The n first-type design modules include the design module D and may also include other design modules besides module D.

Optionally, the division steps include: marking the design module D as a first-type label, marking the mature design module P as a second-type label, assigning the chip design with the first-type label to the microprocessor, and assigning the chip design with the second-type label to the FPGA. It should be noted that the terms “first type” and “second type” in the first-type label and second-type label do not indicate order or importance. “First type” and “second type” are only used to distinguish between the two different labels for design module D, which requires modification, and design module P, which does not require modification. These terms have no other classificatory meaning.

Optionally, the user-specified design module D can also be a modified mature design module P. Any method in the prior art that can separately divide design module D and mature design module P into the microprocessor and FPGA respectively falls within the scope of protection of the present invention.

S640: Allocating physical interconnect links for the transmission signals between the n first-type design modules and the m second-type design modules, resulting in signal transmission configuration modules for both types of design modules.

Signal transmission between design modules can be achieved by allocating physical interconnect links.

Optionally, physical interconnect links are allocated using a routing algorithm. Any other methods of allocating physical interconnect links using routing algorithms fall within the scope of protection of the present invention.

The first-type signal transmission configuration module stores the mapping relationships between the transmission signals of the current first-type design module and other first-type design modules and the physical interconnect links. Additionally, or alternatively, it stores the mapping relationships between the transmission signals of the current first-type design module and second-type design modules and the physical interconnect links.

S660: Compiling each first-type design module and its signal transmission configuration module to generate object code for the microprocessors, resulting in n object code; similarly, compiling each second-type design modules and its signal transmission configuration module to generate bit files for the FPGAs, resulting in m bit files.

S800: Storing the n object code in memories of the n microprocessors and writing the m bit files into the m FPGAs, Controlling the n microprocessors and the m FPGAs to perform emulation and debugging.

As an example, when the first-type design module assigned to the j-th microprocessor is Bⱼ, after undergoing S620 and S640, Bⱼ obtains the first-type executable file Eⱼ, which is stored in the j-th microprocessor through S800.

Regarding hardware emulation turnaround time, the present invention assigns the design module D to the microprocessor. When debugging and correction the design module D, only the microprocessor needs to be recompiled, making the turnaround time of the entire system equal to the turnaround time of the microprocessor. If the DUT is entirely assigned to the FPGA, the turnaround time of the entire system equals the turnaround time of the FPGA. Since the turnaround time of the microprocessor is greater than that of the FPGA, the present invention improves the overall system turnaround time. For example, for a design module, the compilation time for an FPGA is 26 hours, while for a microprocessor, it is 6 hours. If the DUT is entirely assigned to the FPGA, the system compilation time is 26 hours. Using the present invention, the compilation time is 6 hours, thereby increasing the turnaround time compared to assigning the DUT entirely to the FPGA.

Regarding hardware emulation performance, the frequently modified parts are relatively small, while the majority of the mature design is simulated in the FPGA, which has higher simulation performance than the microprocessor. Thus, the overall system simulation performance is close to that of the FPGA.

Therefore, by assigning the design module D to the microprocessor and the mature designs to the FPGA, the present invention achieves a simulation turnaround time equivalent to the microprocessor's turnaround time and a simulation performance close to that of the FPGA. Consequently, the present invention combines the advantages of the microprocessor's turnaround time and the FPGA's simulation performance.

In a preferred embodiment, S600 further includes: S630, optimizing the number of physical interconnection links between the chips.

Further, S630 includes the following steps:

S632, separately obtain the first-type design module Bⱼ assigned to the j-th microprocessor and the second-type design module Fᵢ assigned to the i-th FPGA, where Bⱼ includes submodule Dⱼ of D. The value of j ranges from 1 to n, and the value of i ranges from 1 to m. The partitioner preferentially divides D into the same microprocessor when dividing the module. When the microprocessor cannot accommodate the entire D, the divider divides D into multiple submodules and allocates them to multiple microprocessors separately, where submodule Dⱼ is assigned to the first type of design module Bⱼ of the j-th microprocessor.

S634, obtain Q elements cell={cell₁, cell₂, . . . , cell_{q}, . . . , cell_{Q}} in Fᵢ connected to Dⱼ, where cell_{q} is the q-th element in Fᵢ connected to Di, and the value of q ranges from 1 to Q. It should be noted that elements can be sequential logic units such as registers, flip-flops, or latches, etc. they can also be combinational logic units such as clock gates, etc.

S636, separately obtain the number of physical interconnect links Sum1ᵢ between each element in cell and Dⱼ, and the number of physical interconnect links Sum2ᵢ within Fᵢ. Here, the number of physical interconnect links between cell_{q} and Dⱼ is Sum1_{i,q}, and the number of physical interconnect links within Fᵢ for cell_{q} is Sum2_{i,q}.

S638, When Sum1_{i,q} is greater than Sum2_{i,q}, reallocating cell_{q} to Bⱼ. Reassigning cell_{q} to Bⱼ with more connections can reduce the number of cross-chip connections between the FPGA and the microprocessor, converting inter-chip connections to intra-chip connections, shortening the signal transmission path, reducing latency on the transmission path, and further lowering failure rates by reducing inter-chip connections, thus improving system reliability.

In a preferred embodiment, when the number of physical interconnection links in the microprocessor or FPGA chip is less than the number of signal transmission lines, the corresponding physical interconnection links are multiplexed through multiplexers. This method also includes: S300, configuring multiplexers at the ports of the microprocessors and FPGAs.

Optionally, each port is configured with a time-division multiplexer or frequency-division multiplexer. Other multiplexers in the prior art also fall within the protection scope of the present invention. It should be noted that the same type of time-division multiplexer is configured at the ports at both ends of the same interconnection channel, and different types of multiplexers can be selected for ports of different interconnection channels as needed. Preferably, the multiplexer is a time-division multiplexer (TDM), which is used to transmit multiple signals through one interconnection channel.

In a preferred embodiment, S640 further includes: allocating timeslot resources for the transmission signals between n first type design modules and m second type design modules, inserting multiplexers into each physical interconnection link based on the timeslot resources, resulting in signal transmission configuration modules for n first type design modules and m second type design modules. It should be noted that by allocating timeslot resources, the signal transmission configuration modules of the first and second types of design modules are further optimized.

Optionally, physical interconnection links are allocated for each transmission signal through a routing algorithm, clarifying the physical interconnection link corresponding to each transmission signal, and the allocation of timeslot resources clarifies the timeslot allocation rules among multiple transmission signals on the same physical interconnection link.

Optionally, the timeslot resources are time-division multiplexing ratios.

Preferably, the time-division multiplexing ratio k of the time-division multiplexer combines k input signals into one output signal for transmission.

In a preferred embodiment, the method also includes:

S900, obtaining k memories, each connected to n microprocessors and m FPGAs, and packaging the n microprocessors, m FPGAs, and k memories using chiplet integration, where 0≤k≤K. The chiplet integration packaging method can reduce the interconnection delay between microprocessors, FPGAs, and memories, thereby improving the performance of the heterogeneous simulation system provided by the present invention.

In a preferred embodiment, S900 involves packaging using any of the following methods: interconnecting the n microprocessors, m FPGAs, and k memories through a PCB; interconnecting n microprocessors, m FPGAs, and k memories through a silicon interposer; or interconnecting n microprocessors, m FPGAs, and k memories through through-silicon vias (TSVs).

In a preferred embodiment, the heterogeneous simulation system provided by the present invention can also not be packaged as a whole. In this case, n microprocessors, m FPGAs, and k memories are interconnected through PCB boards or physical wiring, where 0≤k≤K.

Based on the same inventive concept as the above method embodiments, the present invention also provides a system for emulating a chip design with heterogeneous hardware. The system includes interconnected hardware emulators Emu, K memories units, system compiler, and server. The Emu includes N microprocessors and M FPGAs, The compilation time of the object code of the microprocessors is shorter than the compilation time of the bit files of the FPGAs, and the emulation performance of the FPGAs is higher than that of the microprocessors. There are L physical interconnection links between the N microprocessors, the M FPGAs, and K memories, where K≥0, N≥1, M≥1, L≥1. The system compiler includes partitioners, routers, n microprocessor compilers, and m FPGA chip compilers, as shown in FIG. 2, where 0<n≤N and 0<m≤M. Where:

The partitioner is used to divide the chip design DUT into n microprocessors and m FPGAs, where DUT includes the design module D that requires debugging and correction, and is assigned to the microprocessors, resulting in n first type design modules for the microprocessors and m second type of design modules of the FPGAs.

The router is used to allocate physical interconnection links for the transmission signals between the n first type design modules and the m second type design modules, resulting in signal transmission configuration modules of n first type design modules and m second type design modules.

The microprocessor compiler is used to compile generates object code for each first-type design module and its signal transmission configuration module.

The FPGA compiler is used to compile the second-type design modules and its signal transmission configuration modules into the bit files of the FPGA chip.

The server is used to store the n object code in memories of the n microprocessors and write the m bit files into the m FPGAs, and controlling the n microprocessors and the m FPGAs to perform emulation and debugging. It should be noted that the server is equipped with hardware simulation system runtime software that supports the correct operation of the entire hardware simulation system.

In a preferred embodiment, the system also includes multiplexers configured at the ports of the microprocessors and FPGAs.

Preferably, the system compiler also includes a link optimization module for optimizing the number of physical interconnection links between the chips, including a design module acquisition module, an element acquisition module, an interconnection link acquisition module, and a reallocation module.

Wherein the design module acquisition module is used to separately obtain the first type design module Bⱼ assigned to the j-th microprocessor and the second-type design module Fᵢ assigned to the i-th FPGA. Where Bⱼ includes submodule Dⱼ of D, and the value of j range from 1 to n and the value of i range from 1 to m. The element acquisition module is used to obtain Q elements cell={cell₁, cell₂, . . . , cell_{q}, . . . , cell_{Q}} in Fᵢ connected to Dⱼ, where cell_{q} is the q-th element in Fᵢ connected to Dⱼ, and the value of q range from 1 to Q. The interconnection link acquisition module is used to separately obtain the number of physical interconnection links Sum1ᵢ between each element in cell and Dⱼ, and the number of physical links Sum2ᵢ within Fᵢ, The number of physical interconnect links between cell_{q} and Dⱼ is Sum1_{i,q}, and the number of physical links within Fᵢ for cell_{q} is Sum2_{i,q}. The reallocation module reallocates cell_{q} to Bⱼ when Sum1_{i,q} is greater than Sum2_{i,q}.

Preferably, The router is used to allocate physical interconnection links and timeslot resources for the transmission signals between the n first-type design modules and m second-type design modules. The system compiler also includes a multiplexer inserter, which is used to insert multiplexers based on the timeslot resources allocated for each physical interconnection link. In other words, the router also includes an insertion module used to allocate physical interconnection links and timeslot resources for the transmission signals between the n first-type design modules and m second-type design modules, inserting multiplexers into each physical interconnection link based on the timeslot resources, resulting in signal transmission configuration modules of n first type design modules and m second type design modules.

Preferably, the system also includes a packaging module and k memories respectively connected to n microprocessors and m FPGAs. The packaging module is used to package the n microprocessors, m FPGAs, and k memories using chiplet integration, where k>0.

Preferably, the packaging module is any one of the following: a 2D packaging module used to interconnect the n microprocessors, m FPGAs, and k memories through a PCB; a 2.5D packaging module used to interconnect n microprocessors, m FPGAs, and k memories through a silicon interposer; a 3D packaging module used to interconnect n microprocessors, m FPGAs, and k memories through through-silicon vias.

Preferably, the system also includes an interconnection module and k memories. The interconnection module is used to interconnect the n microprocessors, m FPGAs, and k memories through PCB boards or physical connections, where k>0.

It should be noted that the inventive concept of this system embodiment is the same as that of the above method embodiments, where the technical features with the same naming are the same and will not be repeated.

Through this heterogeneous hardware simulation system, the design module is divided into the microprocessor, and the mature design is divided into the FPGA for simulation, combining the advantages of the turnaround time of the microprocessor and the simulation performance of the FPGA.

Although some specific embodiments of the present invention have been described in detail by way of examples, those skilled in the art should understand that the above examples are only for illustration and not for limiting the scope of the present invention. Those skilled in the art should also understand that various modifications can be made to the embodiments without departing from the scope and spirit of the present invention. The scope of the present invention is defined by the appended claims.

What is claimed is:

1. A method for emulating a chip design with heterogeneous hardware, comprising the steps of:
S200: Obtaining interconnected hardware emulators Emu, where the Emu includes N microprocessors and M FPGAs; The compilation time of the object code of the microprocessors is shorter than the compilation time of the bit files of the FPGAs, and the emulation performance of the FPGAs is higher than that of the microprocessors; There are L physical interconnect links between the N microprocessors and the M FPGAs, where N≥1, M≥1, and L≥1;
S400: Obtaining a chip design DUT, which includes a design module D that requires debugging and correction;
S600: Partitioning the DUT to generate n object code for the n microprocessors and m bit files for the m FPGAs, where 0<n≤N and 0<m≤M; This includes:
S620: Partitioning the DUT into n microprocessors and m FPGAs, where D is assigned to the microprocessors, resulting in n first-type design modules for the microprocessors and m second-type design modules for the FPGAs;
S640: Allocating physical interconnect links for the transmission signals between the n first-type design modules and the m second-type design modules, resulting in signal transmission configuration modules for both types of design modules;
S660: Compiling each first-type design module and its signal transmission configuration module to generate object code for the microprocessors, resulting in n object code; Similarly, compiling each second-type design module and its signal transmission configuration module to generate bit files for the FPGAs, resulting in m bit files;
S800: Storing the n object code in memories of the n microprocessors and writing the m bit files into the m FPGAs; Controlling the n microprocessors and the m FPGAs to perform emulation and debugging.

2. The method of claim 1, wherein Step S600 further comprises:
S630: Optimizing the number of physical interconnect links between the chips, including:
S632: Obtaining the first-type design module Bⱼ assigned to the j-th microprocessor and the second-type design module Fᵢ assigned to the i-th FPGA, where Bⱼ includes submodule Dⱼ of D; The value of j ranges from 1 to n, and the value of i ranges from 1 to m;
S634: Obtaining Q elements cell={cell₁, cell₂, . . . , cell_{q}, . . . , cell_{Q}} in Fᵢ connected to Dⱼ, where cell_{q} is the q-th element in Fᵢ connected to Dⱼ; The value of q ranges from 1 to Q;
S636: Obtaining the number of physical interconnect links Sum1ᵢ between each element in cell and Dⱼ, and the number of physical interconnect links Sum2ᵢ within Fᵢ; The number of physical interconnect links between cell_{q} and Dⱼ is Sum1_{i,q}, and the number of physical links within Fᵢ for cell_{q} is Sum2_{i,q};
S638: When Sum1_{i,q} is greater than Sum2_{i,q}, reallocating cell_{q} to Bⱼ.

3. The method of claim 1, further comprising:
S300: Configuring multiplexers at the ports of the microprocessors and FPGAs.

4. The method of claim 1, wherein Step S640 further comprises:
Allocating timeslot resources for the transmission signals between the n first-type design modules and the m second-type design modules, inserting multiplexers into each physical interconnect link based on the timeslot resources, resulting in signal transmission configuration modules for both types of design modules.

5. The method of claim 4, wherein the multiplexers are time-division multiplexers, and the timeslot resources are time-division multiplexing ratios.

6. The method of claim 1, wherein the microprocessors are Boolean processors.

7. The method of claim 1, further comprising:
S900: Obtaining k memories, each connected to the n microprocessors and the m FPGAs, and packaging the n microprocessors, m FPGAs, and k memories using chiplet integration, where k>0.

8. The method of claim 7, wherein Step S900 involves packaging using any of the following methods:
Interconnecting the n microprocessors, m FPGAs, and k memories through a PCB;
Interconnecting the n microprocessors, m FPGAs, and k memories through a silicon interposer;
Interconnecting the n microprocessors, m FPGAs, and k memories through through-silicon vias.

9. The method of claim 1, wherein the n microprocessors, m FPGAs, and k memories are interconnected through a PCB or physical wiring, where k>0.

10. A system for emulating a chip design with heterogeneous hardware, comprising:
Interconnected hardware emulators Emu and a system compiler; The Emu includes N microprocessors and M FPGAs, The compilation time of the object code of the microprocessors is shorter than the compilation time of the bit files of the FPGAs, and the emulation performance of the FPGAs is higher than that of the microprocessors; There are L physical interconnect links between the N microprocessors and the M FPGAs, where N≥1, M≥1, and L≥1;
The system compiler includes:
A partitioner for dividing the chip design DUT into n microprocessors and m FPGAs, where the DUT includes a design module D that requires debugging and correction, and is assigned to the microprocessors, resulting in n first-type design modules for the microprocessors and m second-type design modules for the FPGAs;
A router for allocating physical interconnect links for the transmission signals between the n first-type design modules and the m second-type design modules, resulting in signal transmission configuration modules for both types of design modules;
A microprocessor compiler for compiling each first-type design module and its signal transmission configuration module to generate object code for the microprocessors;
An FPGA compiler for compiling each second-type design module and its signal transmission configuration module to generate bit files for the FPGAs;
A server for storing the n object code in memories of the n microprocessors and writing the m bit files into the m FPGAs, and controlling the n microprocessors and the m FPGAs to perform emulation and debugging.

11. The system of claim 10, wherein the system compiler further comprises:
A link optimization module for optimizing the number of physical interconnect links between the chips, including a design module acquisition module, an element acquisition module, an interconnect link acquisition module, and a reallocation module, wherein:
The design module acquisition module obtains the first-type design module Bⱼ assigned to the j-th microprocessor and the second-type design module Fᵢ assigned to the i-th FPGA, where Bⱼ includes submodule Dⱼ of D; The value of j ranges from 1 to n, and the value of i ranges from 1 to m;
The element acquisition module obtains Q elements cell={cell₁, cell₂, ⋅ ⋅ ⋅ , cell_{q}, . . . , cell_{Q}} in Fᵢ connected to Dⱼ, where cell_{q} is the q-th element in Fᵢ connected to Dⱼ; The value of q ranges from 1 to Q;
The interconnect link acquisition module obtains the number of physical interconnect links Sum1ᵢ between each element in cell and Dⱼ, and the number of physical links Sum2ᵢ within Fᵢ; The number of physical interconnect links between cell_{q} and Dⱼ is Sum1_{i,q}, and the number of physical links within Fᵢ for cell_{q} is Sum2_{i,q};
The reallocation module reallocates cell_{q} to Bⱼ when Sum1_{i,q} is greater than Sum2_{i,q}.

12. The system of claim 10, further comprising:
Multiplexers configured at the ports of the microprocessors and FPGAs.

13. The system of claim 10, wherein the router further comprises:
An insertion module for allocating physical interconnect links and timeslot resources for the transmission signals between the n first-type design modules and the m second-type design modules, and inserting multiplexers into each physical interconnect link based on the timeslot resources, resulting in signal transmission configuration modules for both types of design modules.

14. The system of claim 10, wherein the multiplexers are time-division multiplexers, and the timeslot resources are time-division multiplexing ratios.

15. The system of claim 10, wherein the microprocessors are Boolean processors.

16. The system of claim 10, further comprising:
A packaging module and k memories, each connected to the n microprocessors and the m FPGAs;
The packaging module packages the n microprocessors, m FPGAs, and k memories using chiplet integration, where k>0.

17. The system of claim 16, wherein the packaging module is any of the following:
A 2D packaging module for interconnecting the n microprocessors, m FPGAs, and k memories through a PCB;
A 2.5D packaging module for interconnecting the n microprocessors, m FPGAs, and k memories through a silicon interposer;
A 3D packaging module for interconnecting the n microprocessors, m FPGAs, and k memories through through-silicon vias.

18. The system of claim 10, further comprising:
An interconnect module and k memories; The interconnect module interconnects the n microprocessors, m FPGAs, and k memories through a PCB or physical wiring, where k>0.
